(19) United States
(12) Patent Application Publication
(10) Pub. No.: US 2007/0287248 A1
(43) Pub. Date: Dec. 13, 2007

(54) METHOD FOR MANUFACTURING CAPACITY ELEMENT, METHOD FOR MANUFACTURING SEMICONDUCTOR DEVICE AND SEMICONDUCTOR-MANUFACTURING APPARATUS

(75) Inventor: Kenji MATSUMOTO, Nirasaki-shi (JP)

Correspondence Address: OBLON, SPIVAK, MCCLELLAND MAIER & NEUSTADT, P.C., 1940 DUKE STREET, ALEXANDRIA, VA, 22314, US

(73) Assignee: TOKYO ELECTRON LIMITED, Tokyo (JP)

(21) Appl. No.: 11/834,715

(22) Filed: Aug. 7, 2007

Related U.S. Application Data
(63) Continuation of application No. PCT/JP2006/300250, filed on Jan. 12, 2006.

(30) Foreign Application Priority Data
Feb. 8, 2005 (JP) 2005-031820

(51) Int. Cl. H01L 21/8242; C23C 16/00

(52) U.S. Cl. 438/240; 438/253; 438/396; 118/715

(57) ABSTRACT

A method of manufacturing a capacity element, including the steps of (a) forming an insulating film on a substrate to be processed, (b) forming a lower electrode layer on the insulating film, (c) feeding a vaporized organic solvent onto the lower electrode layer under a condition wherein an oxidizing gas is prevented from feeding in a first step (c1), and feeding one or plural kinds of the organometallic material gas together with the oxidizing gas to the lower electrode layer in a second step (c2), the first step (c1) and the second step (c2) being continuously performed in a chamber, thereby forming a dielectric layer on the lower electrode, and (d) forming an upper electrode layer on the dielectric layer.

### CROSS-REFERENCE TO RELATED APPLICATIONS

This is a Continuation Application of PCT Application No. PCT/JP2006/300250, filed Jan. 12, 2006, which was published under PCT Article 21(2) in Japanese.

This application is based upon and claims the benefit of priority from prior Japanese Patent Application No. 2005-031820, filed Feb. 8, 2005, the entire contents of which are incorporated herein by reference.

### BACKGROUND OF THE INVENTION

1. Field of the Invention

This invention relates to a method for manufacturing a capacity element, to a method of manufacturing a semiconductor device, and to a semiconductor-manufacturing apparatus. In particular, this invention relates to manufacturing techniques and a manufacturing apparatus, which can be suitably applied to the manufacture of a capacity element provided with a dielectric substance made of metal oxide.

2. Description of the Related Art

Conventionally, a semiconductor device is provided with a capacity element comprising a lower electrode having a dielectric layer formed thereon, and an upper electrode formed on this dielectric layer. As for the dielectric layer of this kind of capacity element, it is generally required to have small in leak current and high in dielectric constant in order to secure desirable element properties. Especially, concomitant with the recent trend to further increase the integration of semiconductor device, there is an increasing demand for a capacity element which is small in leak current, compact in size and large in capacity. By the way, a high-dielectric material consisting of metal oxides such as (Ba, Sr)TiO₃ (hereinafter referred to as “BST”) or Ta₂O₅ is now noticed as useful for forming the dielectric layer meeting the aforementioned requirements and is actually employed in a DRAM (Dynamic Access Memory). Further, a ferroelectric material consisting of metal oxides such as Pb(Zr, Ti)O₃ (hereinafter referred to as “PZT”) is now noticed as useful for forming a non-volatile memory and is actually employed in an FeRAM (Ferroelectric Random Access Memory). In this case, although a metal of platinum group elements such as Ir, Ru and Pt is mainly employed as a material for forming a lower electrode, it may be also possible to employ an oxide conductor such as IrO₂, SrRuO₃, etc. in a situation where the relief of polarization fatigue or oxygen barrier properties at high temperatures is required to be seriously taken into consideration. By the way, unless otherwise pointed out in the present specification, the term “dielectric substance” should be understood as including both of “high-dielectric substance” and “ferroelectric substance”.

By the way, as for the method for forming the PZT on the lower electrode, there have been proposed a sol-gel process, a sputtering method, a CVD method, etc. Among them, the sol-gel process is featured in that a solution of sol-gel raw material is coated on a surface of lower electrode and then subjected to annealing treatment in an oxygen atmosphere to polycrystallize the sol-gel raw material, but this sol-gel process is accompanied with problems that the orientation of polycrystallization is non-uniform and that the step coverage property thereof is inferior, thus making it unsuitable for increasing the integration of device. The sputtering method is featured in that a film is formed by making use of a target made of a ceramic sintered body and then subjected to annealing treatment in an oxygen atmosphere, but this sputtering method is accompanied with a problem that it is difficult to optimize the composition of dielectric layer, since the composition of dielectric substance is determined by the target. Further, since the annealing temperature is relatively high in the case of the sputtering method, other layers may be thermally affected by this high annealing temperature, thus raising problems in executing the process.

Under the circumstances described above, an MOCVD (Metal-Organics Chemical Vapor Deposition) method has been noticed as useful for forming a dielectric layer in recent years. For example, there have been proposed various methods for forming a ferroelectric substance such as PZT as seen in JP-A 2000-58525 (KOKAI) (Patent Document 1), JP-A 2002-57156 (KOKAI) (Patent Document 2), JP-A 2002-334875 (KOKAI) (Patent Document 3) and JP-A 2003-318171 (KOKAI) (Patent Document 4). In the case of MOCVD method, since the orientation and crystallinity of the dielectric layer as well as the state of interface between the lower electrode and the dielectric layer have a great influence on the electric properties of capacity element, it is important how to perform the deposition of film on the surface of the lower electrode. In the case of methods described in the aforementioned Patent Documents 1-3, the initial core of dielectric layer is formed at first on the surface of the lower electrode under predetermined conditions and then a regular film formation is performed under modified conditions. Further, in the case of the method described in the aforementioned publication, Patent Document 4, the magnitude of changes in gas pressure and gas temperature are reduced before and after the step of forming the dielectric layer.

Further, there are proposed in JP-A 2003-324101 (KOKAI) (Patent Document 5) a method of changing the concentration of oxidizing gas during the deposition of the dielectric layer and a method of heat-treating the surface of substrate in an atmosphere comprising 100% in concentration of oxygen prior to the deposition of the dielectric layer.

Further, the film quality of the surface of lower electrode and the state of interface that can be created on the occasion of forming a PZT thin film on the lower electrode consisting of IrO₂ by means of the MOCVD method are disclosed in Japan Journal of Applied Physics Vol. 43, No. 5A, 2004, pp 2655-2600, Japan Society of Applied Physics; “Thermochemical Stability of IrO₂ Bottom Electrodes in Direct-Liquid-Injection Metalorganic Chemical Vapor Deposition of Pb(Zr,Ti)O₃ Films”; Kyung-Mun BYUN, et al (Non-patent Document 1). It is reported in this publication that IrO₂ can be easily reduced into Ir by making use of a solvent such as butyl acetate and THF (tetrahydrofuran) or an organometallic material gas (precursor) and that the border between oxidation and reduction is dependent on a ratio of partial pressure between these solvents or precursor and O₂ gas as well as on the temperature of wafer.

Meanwhile, with respect to the electric properties of capacity element, it is strongly demanded by users to improve the fatigue property, imprint property and retention property thereof. The fatigue property is characterized by the decrease of polarization capacity (electrostatic capacity) of capacity element due to the repetition of inversion of polarization. The imprint property is characterized by the hysteresis characteristics of capacity element which is caused to shift in the direction of positive voltage or in the direction of negative voltage. The retention property is characterized by the change with time of polarization capacity (electrostatic capacity) of capacity element.

Although it is assumed that the deterioration of each of aforementioned properties is caused to bring about by the defectives of the state of interface or by the defectives of the structure of dielectric substance such as the oxygen hole at the interface between the electrode and the dielectric substance or the oxygen hole in the dielectric substance, the details of these causes are not yet exactly elucidated. By the way, in the conventional methods set forth in the aforementioned Patent Documents 1-3, when the dielectric layer is formed by the MOCVD, the initial core or initial layer of perovskite-type crystal structure is formed in order to control the state of interface between the lower electrode and the dielectric layer.

On the other hand, depending on the film-forming conditions, the lower electrode constituted by a metallic material such as Ir may be exposed to an oxidizing atmosphere. As described in the aforementioned Non-patent Document 1, when the lower electrode is exposed to an oxidizing atmosphere, the surface of lower electrode may be insufficiently oxidized or a metal oxide having a different composition from that of dielectric layer may be deposited on the surface of lower electrode as explained hereinafter. Further, since the film quality of the dielectric layer can be badly affected by the oxidizing atmosphere, not only the state of interface between the lower electrode and the dielectric layer but also the reproducibility of film quality of dielectric layer may be caused to deteriorate, thus more likely making it difficult to secure the reproducibility of electric properties of capacity element and, at the same time, to stabilize the electric properties of capacity element. Moreover, due to the oxidation of the surface of lower electrode, the surface of lower electrode is roughened (the surface morphology is caused to deteriorate), thus more likely leading to roughening of the surface of dielectric film to be formed on the lower electrode.

However, in the case of the methods set forth in the aforementioned Patent Documents 1, 2, 3 and 5, since the lower electrode is designed to be exposed to an oxidizing atmosphere prior to the deposition of the dielectric layer, there is a possibility of generating an interface layer (impurity oxide layer) such as an IrO₂ layer between the lower electrode and the dielectric layer. In that case, this interface layer may give adverse influences to the electric properties or surface morphology of capacity element. By the way, IrO₂ is an oxide conductive material that can be employed for forming an electrode. In the case of the methods set forth in the aforementioned Patent Documents 1, 2, 3 and 5 however, the conditions for depositing IrO₂ is not controlled at all, so that it is difficult to secure the reproducibility of electric properties (fatigue property, imprint property and retention property) of capacity element, thus possibly rendering these electric properties unstable.

### BRIEF SUMMARY OF THE INVENTION

An object of the present invention is to provide a method of manufacturing a capacity element which is capable of securing the reproducibility and stability of electric properties of capacity element and also capable of smoothening the surface (improvement of surface morphology) of dielectric layer. Other objects of the present invention are to provide a manufacturing method of a semiconductor device and to provide a semiconductor manufacturing apparatus.

In a step of forming a dielectric layer on the lower electrode by means of the MOCVD according to the prior art, the conditions regarding the temperature and pressure inside the chamber are adjusted at first while continuing the introduction of oxidizing gas and inert gas into the chamber, and then an organometallic material gas is fed from a raw material supply system to a route which does not pass through the chamber such as a bypass line, thereby stabilizing the flow rate of the organometallic material gas. Thereafter, when these various conditions are sufficiently stabilized, the organometallic material gas is introduced into the chamber, thereby allowing the reaction between the organometallic material gas and the oxidizing gas to initiate, thus initiating the deposition of the dielectric layer on a substrate.

As a result of studies made by the present inventor on the initial situation on the occasion of starting the process of depositing the dielectric layer as described above, it has been found out by the present inventor that due to the introduction of oxidizing gas into the chamber prior to the introduction of organometallic material gas into the chamber, the surface of the lower electrode made of a metallic material such as Ir or Ru is caused to incompletely oxidize or undesired impurity elements are caused to adhere onto the surface of lower electrode. Further, it has been found most probable that due to these problems, the reproducibility of the state of interface between the lower electrode and the dielectric layer is caused to deteriorate and that due to non-uniformity of the surface structure of the lower electrode, the crystallinity and surface morphology of the dialectic layer is caused to deteriorate, thus deteriorating the reproducibility of electric properties (fatigue property, imprint property and retention property) of capacity element and, at the same time, inviting instability of capacity element.

In view of this, the present inventor has took notice of controlling the feeding oxidizing gas in such a manner that the oxidizing gas is prevented from reaching the surface of lower electrode under the condition where at least one kind of organometallic material gas is not accompanied with the feeding of the oxidizing gas before the initiation of film deposition, thereby making it possible to improve the uniformity, reproducibility and cleanliness of surface condition of the lower electrode before the initiation of film deposition. As a result, it has been made possible to accomplish the present invention as explained below.

The method of manufacturing a capacity element according to the present invention is featured in that it comprises the steps of: (a) forming an insulating film on a substrate to be processed; (b) forming a lower electrode layer on the insulating film; (c) feeding one or plural kinds of organometallic material gas and/or a vaporized organic solvent onto the lower electrode layer under a condition wherein an oxidizing gas is prevented from feeding in a first step (c1), and feeding the organometallic material gas together with the oxidizing gas to the lower electrode layer in a second step (c2), the first step (c1) and the second step (c2) being continuously performed in a chamber, thereby forming a dielectric layer on the lower electrode; and (d) forming an upper electrode layer on the dielectric layer.

In the first step (c1), only the one or plural kinds of organometallic material gas may be fed or only a vaporized organic solvent may be fed onto the lower electrode layer. Alternatively, at least one kind of organometallic material gas may be fed together with a vaporized organic solvent to the lower electrode layer in the first step (c1).

The organometallic material gas to be fed in the first step (c1) may be the same in composition as that of the organometallic material gas to be fed in the second step (c2). The partial pressure of the organometallic material gas to be employed in the first step (c1) should preferably be substantially the same as that of the organometallic material gas to be employed in the second step (c2).

In the present invention, the lower electrode layer to be formed in the step (b) should preferably comprise a platinum group element. It would be more effective if the platinum group element is selected from Ir and Ru. Further, the dielectric substance to be formed in the step (c) should preferably be a ferroelectric substance. It would be especially effective if the dielectric substance to be formed in the step (c) is formed of Pb(Zr, Ti)O₃. Further, the organometallic material gas should preferably be one which can be created through the vaporization of a solution of organometallic material in a vaporizer. In this case, the solution of organometallic material should preferably be one which can be created through the dissolution of the organometallic material in an organic solvent. As for the organic solvent, it is possible to employ butyl acetate.

In the aforementioned manufacturing method of a capacity element, the aforementioned metallic layer is generally employed as the lower electrode and the upper electrode is formed on the dielectric layer, thereby fabricating the capacity element. In this case, the lower electrode as well as the upper electrode may be constituted by a single layer or by a plurality of conductive layers.

The method of manufacturing a semiconductor device according to the present invention is featured in that it comprises the steps of: (a) selectively removing the surface of a substrate to be processed to form an element isolation film; (b) injecting an impurity to specific regions of element region to form a source region and a drain region; (c) forming a gate insulating film at a space between the source region and the drain region; (d) forming a gate electrode on the gate insulating film; (e) forming an interlayer insulating film to thereby cover the element isolation region and the gate electrode; (f) forming a contact hole in the interlayer insulating film; (g) forming a first metallic layer on a surface of the interlayer insulating film in a manner to enable the first metallic layer to be electrically connected, via the contact hole, with the source region and/or the drain region; (h) feeding one or plural kinds of organometallic material gas and/or a vaporized organic solvent onto the first metallic layer under a condition wherein an oxidizing gas is prevented from feeding in a first step (h1), and feeding the organometallic material gas together with the oxidizing gas to the surface of the first metallic layer in a second step (h2), the first step (h1) and the second step (h2) being continuously performed in a chamber, thereby forming a dielectric layer on the first metallic layer; and (i) forming a second metallic layer on the dielectric layer.

The semiconductor manufacturing apparatus according to the present invention comprises: a chamber which is equipped with a mounting table for supporting a substrate and configured to surround the substrate; a raw material feeding section for feeding one or plural kinds of organometallic material gas, an oxidizing gas and a vaporized organic solvent, respectively, to the chamber; an exhaust section for exhausting the interior of the chamber; and a control section for controlling the raw material feeding section in such a manner that the one or plural kinds of organometallic material gas and/or the vaporized organic solvent are fed into the chamber from the raw material feeding section without feeding the oxidizing gas into the chamber in a first time period, and then the organometallic material gas is fed together with the oxidizing gas into the chamber from the raw material feeding section in a second time period, and that a feeding action in the first time period and a feeding action in the second time period are successively executed.

The control section may be controlled in such a manner that only the one or plural kinds of organometallic material gas is fed or only a vaporized organic solvent is fed into the chamber from the raw material feeding section in the first time period. Alternatively, a vaporized organic solvent is fed into the chamber and, at the same time, at least one kind of organometallic material gas is fed into the chamber in the first time period.

At least one kind of organometallic material gas to be fed in the first time period should preferably be substantially the same in composition as that of the organometallic material gas to be fed in the second time period. Since the gas to be employed in the first time period is made substantially the same with the gas to be employed in the second time period, the treating process of the second time period is enabled to be suitably executed in succession to the treating process of the first time period. This semiconductor manufacturing apparatus may be equipped with a vaporizer for vaporizing a solution of organometallic material to generate an organometallic material gas. Preferably, in order to prevent the condensation of the organometallic material gas, the organometallic material gas should be heated with the length of pipe line between the vaporizer and the treating chamber being made as short as possible.

### BRIEF DESCRIPTION OF THE SEVERAL VIEWS OF THE DRAWING

FIG. 1 is a block diagram illustrating the general structure of the semiconductor manufacturing apparatus according to one embodiment of the present invention;

FIG. 2 is a fluid circuit diagram illustrating the raw material feeding section of semiconductor manufacturing apparatus;

FIG. 3 is a diagram illustrating the control of semiconductor manufacturing apparatus;

FIG. 4 is a timing chart illustrating the changes of flow rate of various gases (a)-(e) in the film-forming process of Comparative Example;

FIG. 5 is a timing chart illustrating the changes of flow rate of various gases (a)-(e) in the film-forming process of Example;

FIG. 6 is a cross-sectional view schematically illustrating the capacity element to be disposed in a semiconductor device;

FIG. 7 is a cross-sectional view schematically illustrating the FeRAM to be disposed in a semiconductor device;

FIG. 8 is a graph illustrating the amount of elements adhered onto the substrate in various atmospheres before the step of forming a film;

FIG. 9 is a graph illustrating part of XRD profile to the PZT/Ru structure of Example and to the PZT/Ru structure of Comparative Example; and

FIG. 10 is a cross-sectional view of the PZT/Ru structure of Example and the PZT/Ru structure of Comparative Example, which are depicted side by side.

### DETAILED DESCRIPTION OF THE INVENTION

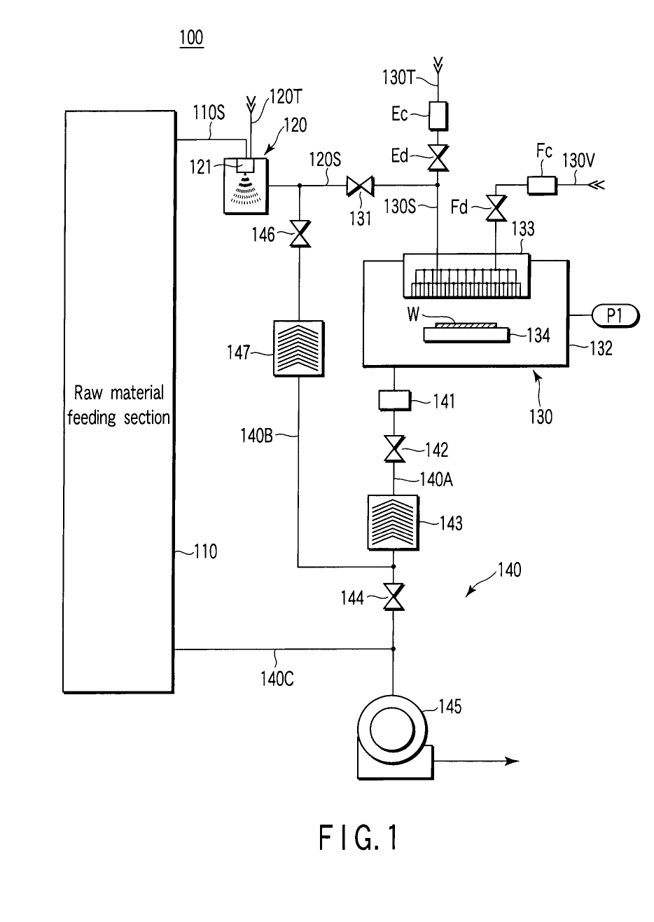

Next, the best mode of carrying out the present invention will be explained with reference to the drawings attached herewith. FIG. 1 is a block diagram schematically illustrating the general structure of the semiconductor manufacturing apparatus 100 according to this embodiment. This semiconductor manufacturing apparatus 100 is an MOCVD apparatus which is equipped with a liquid material-vaporizing/supplying system for vaporizing and feeding a liquid material formed of a liquid organic metal or an organometallic solution.

(Construction of Apparatus)

The semiconductor manufacturing apparatus 100 is equipped with a raw material feeding section 110, a vaporizer (liquid vaporizing section) 120, a treatment section 130, and an exhaustion section 140. The raw material feeding section 110 is designed to feed a liquid organic metal, an organometallic solution or a liquid material such as an organic solvent. The vaporizer (liquid vaporizing section) 120 is designed to generate gas to be created through the vaporization of a liquid material supplied from the raw material feeding section 110. The treatment section 130 is designed to perform the formation of film by making use of the gas that has been supplied from the vaporizer 120. The exhaustion section 140 is designed to exhaust the atmosphere of the vaporizer 120, of the treatment section 130 and of the raw material feeding section 110.

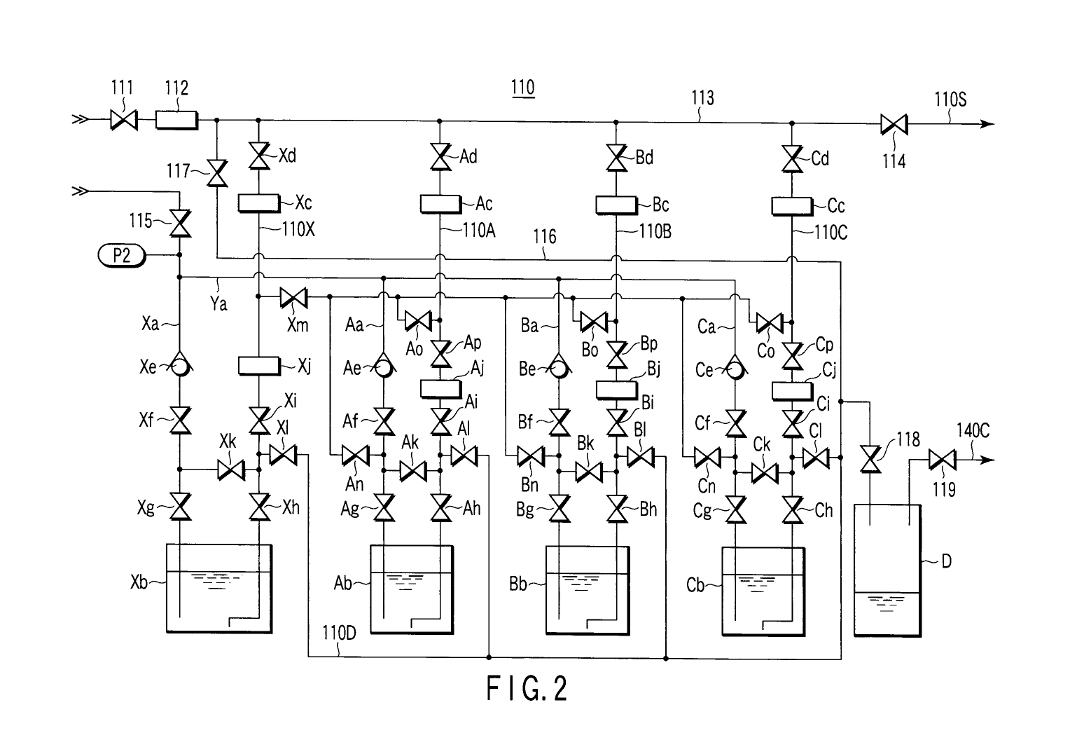

FIG. 2 is a fluid circuit diagram of the raw material feeding section 110. This raw material feeding section 110 is constituted by a solvent supply section, an “A” material supply section, a “B” material supply section, and a “C” material supply section. The solvent supply section comprises a pressing line Xa, a solvent vessel Xb and a supply line 110X. The solvent vessel Xb is designed to preserve therein an organic solvent having a predetermined composition. The pressing line Xa is interposed between the supply source (not shown) of a pressurized inert gas (for example, compressed nitrogen gas) and the solvent vessel Xb, and is designed to introduce the pressurized inert gas into the solvent vessel Xb and then feed, under pressure, an organic solvent from the solvent vessel Xb. The pressurizing line Xa is equipped with an on-off valve 115, a pressure gage P2, a check valve Xe, an on-off valve Xf and an on-off valve Xg. The supply line 110X is interposed between the solvent vessel Xb and a main line (a raw material supply line) 110S and is designed to pass the organic solvent from the solvent vessel Xb to the main line 110S. The supply line 110X is equipped with an on-off valve Xh, an on-off valve Xi, a filter Xj, a flow rate controller Xc and an on-off valve Xd.

The “A” material supply section is equipped with a pressurizing line Aa, a raw material vessel Ab and a supply line 110A. The raw material vessel Ab is designed to preserve a liquid organometallic raw material or a solution of an organometallic raw material (hereinafter referred to simply as “raw material”). The pressurizing line Aa is connected, via a branch line Ya which is diverged downstream of a pressure gage P2, to the aforementioned pressurizing line Xa. The pressurizing line Aa is provided with a check valve Ae, an on-off valve Af and an on-off valve Ag. The supply line 110A is interposed between the raw material vessel Ab and the main line 110S and is designed to pass a raw material from the raw material vessel Ab to the main line 110S. The supply line 110A is equipped with an on-off valve Ah, an on-off valve Ai, a filter Aj, an on-off valve Ap, a flow rate controller Ac and an on-off valve Ad.

The “B” material supply section is equipped with a pressurizing line Ba, a raw material vessel Bb and a supply line 110B. The raw material vessel Bb is designed to preserve a different raw material. The pressurizing line Ba is connected, via a branch line Ya which is diverged downstream of a pressure gage P2, to the aforementioned pressurizing line Xa. The pressurizing line Ba is provided with a check valve Be, an on-off valve Bf and an on-off valve Bg. The supply line 110B is interposed between the raw material vessel Bb and the main line 110S and is designed to pass a raw material from the raw material vessel Bb to the main line 110S. The supply line 110B is equipped with an on-off valve Bh, an on-off valve Bi, a filter Bj, an on-off valve Bp, a flow rate controller Bc and an on-off valve Bd.

The “C” material supply section is equipped with a pressurizing line Ca, a raw material vessel Cb and a supply line 110C. The raw material vessel Cb is designed to preserve a different raw material. The pressurizing line Ca is connected, via a branch line Ya which is diverged downstream of a pressure gage P2, to the aforementioned pressurizing line Xa. The pressurizing line Ca is provided with a check valve Ce, an on-off valve Cf and an on-off valve Cg. The supply line 110C is interposed between the raw material vessel Cb and the main line 110S and is designed to pass a raw material from the raw material vessel Cb to the main line 110S. The supply line 110C is equipped with an on-off valve Ch, an on-off valve Ci, a filter Cj, an on-off valve Cp, a flow rate controller Cc and an on-off valve Cd.

When it is desired to form a dielectric thin film of PZT, an organic solvent such as butyl acetate, octane, hexane, THF(tetrahydrofuran), etc. can be employed as the aforementioned organic solvent. Further, as for the raw material to be supplied from the “A” material supply section, it is possible to employ an organic Pb material such as Pb(DPM)₂, etc. As for the raw material to be supplied from the “B” material supply section, it is possible to employ an organic Zr material such as Zr(O-i-Pr)(DPM)₃, Zr(O-i-Pr)₂(DPM)₂, Zr(DPM)₄, etc. Further, as for the raw material to be supplied from the “C” material supply section, it is possible to employ an organic Ti material such as Ti(O-i-Pr)₂(DPM)₂, etc. Since these organic Pb material, organic Zr material and organic Ti material are all solid under normal temperature and pressure, they should preferably be dissolved in any of the aforementioned organic solvents at a predetermined concentration, thus enabling them to be used as a solution of raw material. However, it is also possible to employ a liquid organic Zr raw material such as Zr(O-t-Bu)₄ or a liquid organic Ti raw material such as Ti(O-i-Pr)₄. By the way, the present invention is not limited to the aforementioned raw materials but various kinds of organometallic materials can be employed in the present invention. For example, if a film of BST is to be formed, organic Ba materials as well as organic Sr material can be employed as a raw material. Although the organometallic materials (raw materials) to be employed may be liquid or solid at normal temperature, the organometallic material employed in this example was dissolved in an organic solvent such as butyl acetate for using it as a solution.

In the aforementioned “A” material supply section, “B” material supply section and “C” material supply section, each of the on-off valves Xh, Ah, Bh and Ch, each of the on-off valves Xi, Ai, Bi and Ci, each of the filters Xj, Aj, Bj and Cj, each of the on-off valves Ap, Bp and Cp, each of the flow controllers Xc, Ac, Bc and Cc each constituted by a mass flow meter and a flow rate controlling valve, and each of the on-off valve Xd, Ad, Bd and Cd are successively attached, in the mentioned order starting from the upstream side, to each of the aforementioned supply lines 110X, 110A, 110B and 110C, respectively, these supply lines 110X, 110A, 110B and 110C being ultimately connected with a raw material mixing section 113. Further, each of the check valves Xe, Ae, Be and Ce, each of the on-off valves Xf, Af, Bf and Cf, and each of the on-off valves Xg, Ag, Bg and Cg are successively attached, in the mentioned order starting from the upstream side, to each of the aforementioned pressurizing lines Xa, Aa, Ba and Ca, respectively.

An intermediate portion between each of the on-off valves Xf, Af, Bf and Cf and the on-off valves Xg, Ag, Bg and Cg on the aforementioned pressurizing lines Xa, Aa, Ba and Ca is connected, via each of on-off valves Xk, Ak, Bk and Ck, with an intermediate portion between each of the on-off valves Xi, Ai, Bi and Ci and the on-off valves Xh, Ah, Bh and Ch on the aforementioned supply lines 110X, 110A, 110B and 110C. Further, an intermediate portion between each of the on-off valves Xi, Ai, Bi and Ci and the on-off valves Xh, Ah, Bh and Ch on the aforementioned supply lines 110X, 110A, 110B and 110C is connected, via each of on-off valves X1, A1, B1 and C1, with the exhaust line 110D.

An intermediate portion between the filter Xj and the flow controllers Xc on the aforementioned supply lines 110X is connected, via the on-off valves Xm, An, Bn and Cn, with the pressurizing lines Aa, Ba and Ca, and also connected, via the on-off valves Xm, Ao, Bo and Co, with the supply lines 110A, 110B and 110C.

Upstream portions of the aforementioned pressurizing lines Xa, Aa, Ba and Ca are connected with each other and respectively connected, via an on-off valve 115, with a pressurizing gas source such as inert gas source. The downstream side of the on-off valve 115 is provided with a pressure gage P2. Further, the exhaust line 110D is connected with a bypass line 116 and also connected with the raw material mixing portion 113 via an on-off valve 117. A downstream end of this raw material mixing portion 113 is connected, via an on-off valve 114, with the main line 110S which is introduced into the vaporizer 120. Further, an upstream end of this raw material mixing portion 113 is connected, via an on-off valve 111 and a flow rate controller 112, with a carrier gas source such as an inert gas source. The exhaust line 110D is connected, via an on-off valve 118, with a drain tank D, which is connected, via an on-off valve 119, with a raw material supply/exhaust line 140C.

As shown in FIG. 1, the vaporizer 120 is provided with a spray nozzle 121 which is connected not only with the main line 110S extended out of the raw material feeding section 110 but also with a spray gas line 120T which is designed to feed a spray gas (for example, inert gas). It is designed such that when a mist of liquid material is injected into the heated vaporizer 120 by means of this spray nozzle 121, the liquid material is vaporized to create a raw material gas. This vaporizer 120 is connected with a gas supply line 120S, which is connected, via a gas inlet valve 131, with the treating section 130. This gas supply line 120S is connected with a carrier gas supply line 130T which is designed to feed a carrier gas such as inert gas, so that the carrier gas is enabled to be introduced, via a gas supply line 130S, into the treating section 130 together with a raw material gas. The carrier gas supply line 130T is provided with a flow rate controller Ec and an on-off valve Ed, thus making it possible to control the flow rate of the carrier gas by means of this flow rate controller Ec.

In order to supply the treating section 130 with an oxidizing gas such as O₂, O₃, N₂O, NO₂, etc., an oxidizing gas line 130V is connected with a single or plural gas supply sources (not shown). This oxidizing gas line 130V is provided with a flow rate controller Fc and an on-off valve Fd, thereby enabling the flow rate of the oxidizing gas to be controlled by means of the flow rate controller Fc. By the way, if required, an additional carrier gas supply line may be provided other than the aforementioned line 130V. Although not shown in the drawings, specific examples of the additional carrier gas supply line may include: a carrier gas supply line which is designed to purge the oxidizing gas and connected with a downstream portion of the oxidizing gas line 130V; a carrier gas supply line which is designed for the purging of the inlet/outlet gate valve (not shown) of a substrate W; and a carrier gas supply line which is designed for the purging of the shield plate (not shown) disposed in a chamber 132.

The treating section 130 is provided with the chamber 132 which is constituted by an air-tight closed vessel and employed as a film-forming chamber. This chamber 132 is provided with a gas inlet portion 133 which is connected with the aforementioned gas lines 130S and 130V. The gas inlet portion 133 is provided with a shower head structure for introducing a raw material gas and an oxidizing gas into the interior of the chamber 132 from fine apertures. This shower head structure is formed of a post-mix type inlet structure in the case of embodiment shown herein wherein a raw material gas and an oxidizing gas are individually introduced into the interior of the chamber 132 from fine apertures which are separately installed at the gas inlet portion 133. Further, the chamber 132 is provided therein with a susceptor 134 which is disposed to face the gas inlet portion 133. It is designed such that a substrate W to be treated can be placed on this susceptor 134. This susceptor 134 is designed to be heated by a heater or an irradiating apparatus (both not shown) to thereby keep the substrate W at a predetermined set temperature. By the way, the pressure gage P1 is designed to measure the pressure inside the chamber 132.

The exhaustion section 140 is provided with a main exhaust line 140A which is connected with the chamber 132. This main exhaust line 140A is provided with, mentioning from the upstream side, a pressure-adjusting valve 141, an on-off valve 142, an exhaust trap 143, an on-off valve 144 and an exhaust device 145. The pressure-adjusting valve (or automatic pressure-adjusting means) 141 is designed to control the opening degree of valve in conformity with the pressure detected of the pressure gage P1 and to automatically adjust the inner pressure of chamber 132 to a set value.

Further, the exhaustion section 140 is provided with a bypass exhaust line 140B which is connected with the gas supply line 120S and also with the main exhaust line 140A. An upstream end of this bypass exhaust line 140B is connected with an intermediate portion between the vaporizer 120 and the gas inlet valve 131, and a downstream end of this bypass exhaust line 140B is connected with an intermediate portion between the exhaust trap 143 and an on-off valve 144. The bypass exhaust line 140B is provided successively with, mentioning from the upstream side, an on-off valve 146 and an exhaust trap 147.

Further, the exhaustion section 140 is provided with the aforementioned raw material supply/exhaust line 140C which is extended out to the raw material feeding section 110. This raw material supply/exhaust line 140C is connected with an intermediate portion between the on-off valve 144 of main exhaust line 140A and the exhaust device 145. This exhaust device 145 is designed to evacuate the chamber 132 and is preferably constituted for example by a two-stage linear structure wherein the first stage is constituted by a mechanical booster pump and the second stage is constituted by a dry pump.

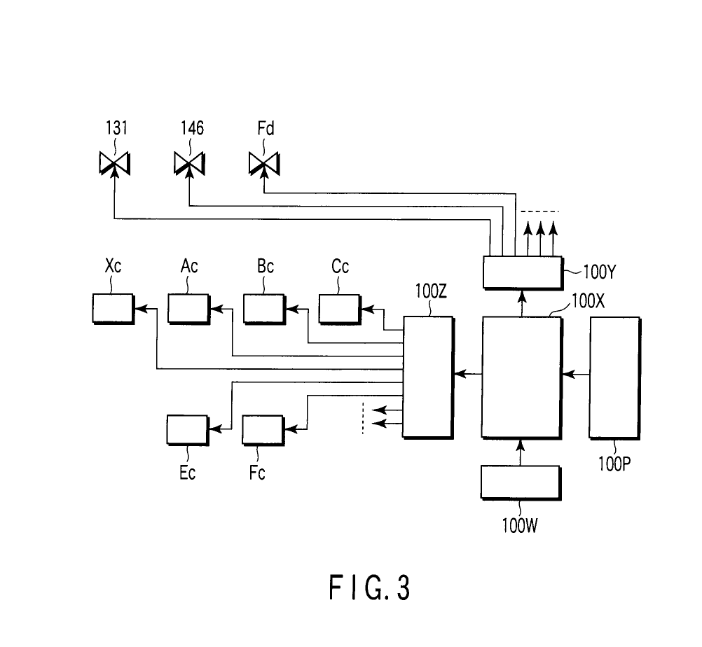

Next, the control system of the semiconductor manufacturing apparatus will be explained with reference to FIG. 3.

The control system according to this embodiment is provided with a main control section 100X having an MPU (microprocessing unit), an operating section 100P, an on-off valve control section 100Y, a flow rate control section 100Z and a detection signal input section 100W. The manipulating section 100P is provided with an operating panel and a screen for executing various kinds of input to the main control section 100X. The on-off valve control section 100Y is designed to transmit a signal for controlling the actions of on-off valves 131, 146, Fd, etc. based on the instructions from the main control section 100X. By the way, instead of controlling the ON/OFF of the on-off valve Fd, the flow rate of the flow rate controller Fc may be controlled, thereby determining the introduction or non-introduction of an oxidizing gas into the treating section 130. The flow rate control section 100Z is designed to receive signals from a flow rate detector and to transmit signals for controlling the actions of the flow rate controllers Xc, Ac, Bc and Cc, etc. The detection signal input section 100W is designed to receive detection signals from various kinds of sensors (not shown) and to transmit detected value signals to the main control section 100X in conformity with the detection signals.

The flow rate control section 100Z is connected with the aforementioned flow rate controllers Xc, Ac, Bc, Cc, Ec and Fc to set the flow rate thereof. In this case, the flow rate controllers Xc, Ac, Bc, Cc, Ec and Fc may be controlled in such a manner that the flow rate detection values that have been output from these flow rate controllers Xc, Ac, Bc, Cc, Ec and Fc are once fed back to the flow rate control section 100Z in which these flow rate detection values are adjusted so as to identical with the set values. In this case, these flow rate controllers Xc, Ac, Bc, Cc, Ec and Fc may be respectively constituted by a flow rate detector such as an MFM (mass flowmeter), and a flow rate adjusting valve such as a high-precision flow rate variable valve.

As described above, this embodiment is featured in that it includes a step of reacting a raw material gas comprising an organic metal material with an oxidizing gas to form a dielectric layer consisting of a metal oxide on the surface of substrate (metal layer). This step is executed by making use of the aforementioned semiconductor manufacturing apparatus 100. As for the dielectric layer, it is possible to employ either a high-dielectric layer or a ferroelectric layer depending on the end-use thereof. As for the ferroelectric layer, a polycrystalline thin film having a perovskite-type structure such as PZT or a polycrystalline thin film having a laminar structure such as SBT can be preferably employed.

### EXAMPLES

Next, the manufacturing step of the dielectric layer and the operation of the semiconductor manufacturing apparatus in this manufacturing step will be explained. This semiconductor manufacturing apparatus 100 is designed to be automatically operated as a whole through the execution of operating program in the control section 100X shown in FIG. 3. For example, the operating program is stored in advance in the inner memory of MPU, so that this inner memory is read out at first and then executed by CPU. Preferably, this operating program should be constructed such that it includes various kinds of operating parameters and that these operating parameters can be suitably set by the input operation of the operating section 100P.

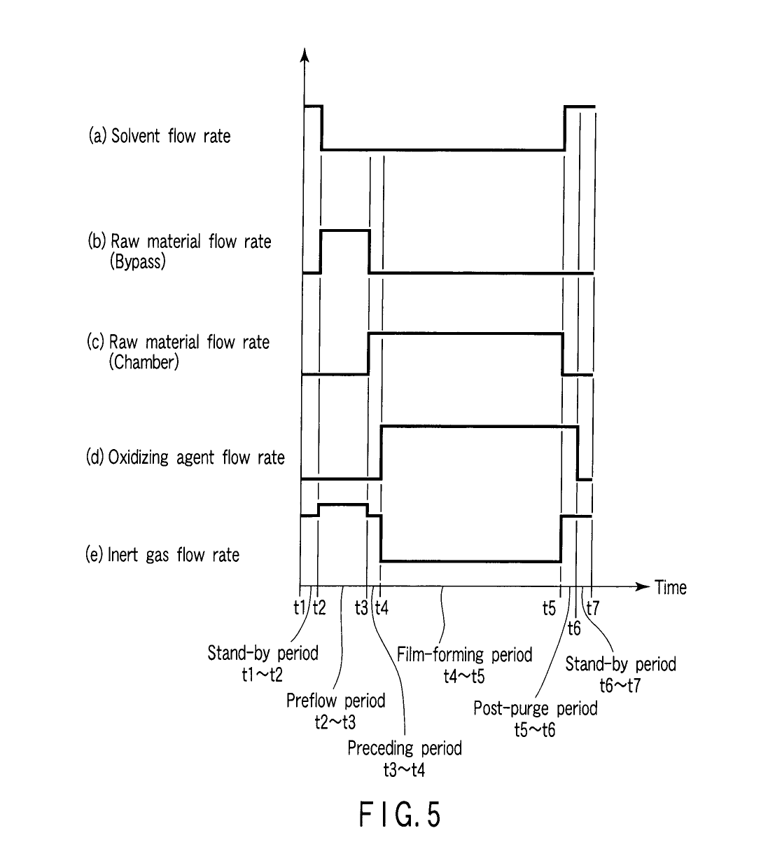

FIG. 5 shows a timing chart illustrating the operating timing of various portions of the semiconductor manufacturing apparatus 100. (a) in FIG. 5 shows the flow rate of a solvent to be fed by way of the supply line 110X. This flow rate of solvent is controlled by the flow rate controller Xc.

(b) in FIG. 5 shows the flow rate of raw material (bypass). (c) in FIG. 5 shows the flow rate of raw material (chamber). The flow rate of raw material (bypass) corresponds to a flow rate passing through the bypass exhaust line 140B among the flow rates of raw material gas that has been vaporized by the vaporizer 120. Further, the flow rate of raw material (chamber) corresponds to a flow rate passing through the raw material gas supply line 130S. A total of these raw material flow rate (bypass) and raw material flow rate (chamber) corresponds to a total flow rate of the raw material to be fed through the supply lines 110A, 110B and 110C. This total of flow rates can be controlled by the flow rate controllers Ac, Bc and Cc.

(d) in FIG. 5 shows the flow rate of oxidizing agent. The flow rate of oxidizing agent corresponds to a flow rate passing through the oxidizing gas line 130V. (e) in FIG. 5 shows the flow rate of inert gas. The flow rate of inert gas corresponds to a total flow rate of inert gas such as nitrogen gas passing through all of carrier gas supply lines including the carrier gas supply line 130T. By the way, each of the flow rates shown in (a)-(e) of FIG. 5 is indicated by a different flow rate scale from others.

First of all, a semiconductor substrate W is placed in the chamber 132 and mounted on the susceptor 134. At the timing t1, the feeding of inert gas such as nitrogen gas into the chamber 132 is initiated at an inert gas flow rate shown in (e) of FIG. 5. In the time period from the timing t1 to the timing t2, inert gas such as nitrogen gas is continued to flow at a constant flow rate. In this stand-by time period t1-t2, the stabilization of the flowing state and vaporizing state of vaporizer 120 is performed. In this stand-by time period t1-t2, the flow rate of solvent is set to 1.2 mL/min (200 sccm, when calculated as gas) for example, and a total flow rate of inert gas is set to 1200 sccm. By the way, the flow rate of the carrier gas to be fed to the raw material mixing section 113 of raw material feeding section 110 is set to 200 sccm for example, and the flow rate of the spray gas to be fed to the vaporizer 120 is set to 50 sccm. Irrespective of the stand-by time period t1-t2, the flow rates of these carrier gas and spray gas are always made constant in order to maintain the spraying state of the vaporizer 120. Further, in this stand-by time period t1-t2, since a liquid raw material is not fed to the vaporizer 120, a raw material gas is not permitted to generate in the vaporizer 120. This stand-by time period t1-t2 should preferably be set to about 20-40 seconds for example.

In the next preflow time period t2-t3, a liquid raw material is permitted to flow as shown by the raw material flow rate (bypass) (FIG. 5(b)), the flow rate of solvent is decreased (FIG. 5(a)), and the flow rate of inert gas is increased (FIG. 5(e)). In this preflow time period t2-t3, the flow rate of liquid material is set to 0.5 mL/min, the flow rate of solvent is set to 0.7 mL/min, and the flow rate of inert gas is set to 2900 sccm. As described above, a total supply rate of the liquid consisting of the solvent and the liquid material during the stand-by time period t1-t2 and the preflow time period t2-t3 should preferably be constant. Since a liquid raw material is fed in this preflow time period t2-t3 as described above, the raw material and the solvent are vaporized in the vaporizer 120, thus generating the raw material gas. Then, the gas inlet valve 131 is closed and the on-off valve 146 is opened, thereby permitting the raw material gas to discharge through the bypass exhaust line 140B. Due to the treatment in this preflow time period t2-t3, it is now possible to feed the raw material gas to the chamber 132 at a stabilized flow rate in the subsequent time periods, i.e. the preceding period (lead time) t3-t4 and the film-forming time period t4-t5. By the way, this stand-by time period t1-t2 should preferably be set to about 30-150 seconds for example.

By the way, in the stand-by time period t1-t2 or the preflow time period t2-t3, the substrate W is heated on the susceptor 134 and set to a predetermined temperature and, at the same time, the interior of the chamber 132 is evacuated by means of an exhaust device 145 and set to a predetermined pressure. In this embodiment, the temperature of the substrate W in the film-forming time period t4-t5 should preferably be set to 500-650° C., more preferably about 600-630° C. Further, the inner pressure of the chamber 132 in the film-forming time period t4-t5 should preferably be set to the range of 50 Pa-5 kPa, more preferably to about 533.3 Pa.

After the flow rate of raw material gas is stabilized in the aforementioned preflow time period t2-t3, the gas inlet valve 131 is opened and the on-off valve 146 is closed as indicated by (c) in FIG. 5 raw material flow rate (chamber), thus introducing the raw material gas into the chamber 132. By the way, this raw material gas is introduced together with a gas of the organic solvent. In the preceding period t3-t4 in which the raw material gas has been initially introduced into the chamber 132, the supply of oxidizing gas is not executed at all as indicated by (d) in FIG. 5.

In this case, it is preferable to reduce the flow rate of inert gas that has been fed by way of the carrier supply line 130T concurrent with the introduction of the raw material gas into the chamber, thereby adjusting a total gas flow rate to be introduced into the chamber 132 and preventing it from being substantially changed. For example, when the flow rate of the raw material gas to be introduced into the chamber 132 is set to 0.5 mL/min and the flow rate of the solvent is set to 0.7 mL/min, the flow rate of inert gas can be reduced by a corresponding amount of 200 sccm. In this preceding period t3-t4, since the supply of oxidizing agent is prevented, the surface of substrate W is brought into a state wherein raw material molecule is uniformly adsorbed thereon, thus suppressing the influence of the underlying layer. This preceding period t3-t4 should preferably be continued until the raw material gas can be uniformly and stably fed over the surface of substrate in the chamber. For example, this preceding period t3-t4 should preferably be set to 10-60 seconds or so for example.

When the preceding period t3-t4 is terminated, an oxidizing gas is permitted to enter into the chamber 132 at the timing t4 as indicated by FIG. 5(d), thus initiating the deposition of film to the substrate W in the chamber 132. On this occasion, since the molecules of raw material are existed on the surface of substrate, it is possible to obtain a film having a uniform and flat surface. It is preferable to reduce the flow rate of inert gas by a flow rate which corresponds to the amount introduced of the oxidizing gas, thereby adjusting a total gas flow rate to be introduced into the chamber 132 and preventing it from being substantially changed. For example, when the flow rate of the oxidizing gas is set to 2000 sccm, the flow rate of inert gas can be reduced by 2000 sccm concurrent with the introduction of the oxidizing gas.

In the film-forming time period t4-t5, the raw material gas is reacted with the oxidizing gas to form a dielectric layer on the surface of substrate W. Although this film-forming time period t4-t5 depends on the kinds of raw material gas and oxidizing gas, on the composition of the dielectric layer, on the film-forming temperature (the temperature of substrate W on the occasion of forming the film), and on the thickness of the dielectric layer, it is generally set to the range of 100-500 seconds.

When the formation of film on the substrate W is finished (when the predetermined film-forming time is expired), the gas inlet valve 131 is closed and the on-off valve 146 is opened, thus shifting the process to a post-purge time period t5-t6 to be executed after the formation of film. Further, the supply of the oxidizing gas is suspended at the timing t6 as indicated by (d) in FIG. 5 and a stand-by time period t6-t7 is initiated wherein only the purging of inert gas is performed. By the way, the flow rate of raw material gas in the preceding period t3-t4 should preferably be made equal to the flow rate of raw material gas in the film-forming time period t4-t5.

By the way, in the post-purge time period t5-t6, the introduction of oxidizing gas is continued in order to prevent the deterioration of the dielectric layer (PZT), thereby maintaining the oxidizing atmosphere inside the chamber 132. The treatment in the post-purge time period t5-t6 differs from the treatment of the preflow time period t2-t3 in the respect that the supply of oxidizing gas is continued. The reason for this is that when a ferroelectric substance having a perovskite-type crystal structure is disposed in a reducing atmosphere and high temperature, the dielectric properties thereof is generally caused to greatly deteriorate due to the dissociation of oxygen. In this example, the introduction of oxygen is continued in the post-purge time period t5-t6 after the deposition of the film, thus preventing the interior of chamber 132 from being turned into a reducing atmosphere. On the contrary, when the interior of chamber 132 is made into an oxidizing atmosphere, the deterioration in properties of ferroelectric substance can be completely prevented.

By the way, it is possible in this apparatus 100 to repeatedly perform a plurality of film-forming process by repeating the treatments of: the preflow time period→the preceding period→the film-forming time period→the post purge time period subsequent to the stand-by time period t6-t7. Namely, although FIG. 5 shows only a single film-forming process, it is also possible to perform the film-forming process only once or to perform successively two or more film-forming processes with a substrate W-interchanging work being interposed therebetween.

The operating timing of each section mentioned above may be preset in the control section 100X. Alternatively, the operating timing may be suitably set through the operation of the operating section 100P. Once the operating timing is set, the apparatus can be automatically controlled as a whole, through the on-off valve control section 100Y and the flow rate control section 100Z, by means of the control section 100X, thus executing the aforementioned operating procedures.

### COMPARATIVE EXAMPLE

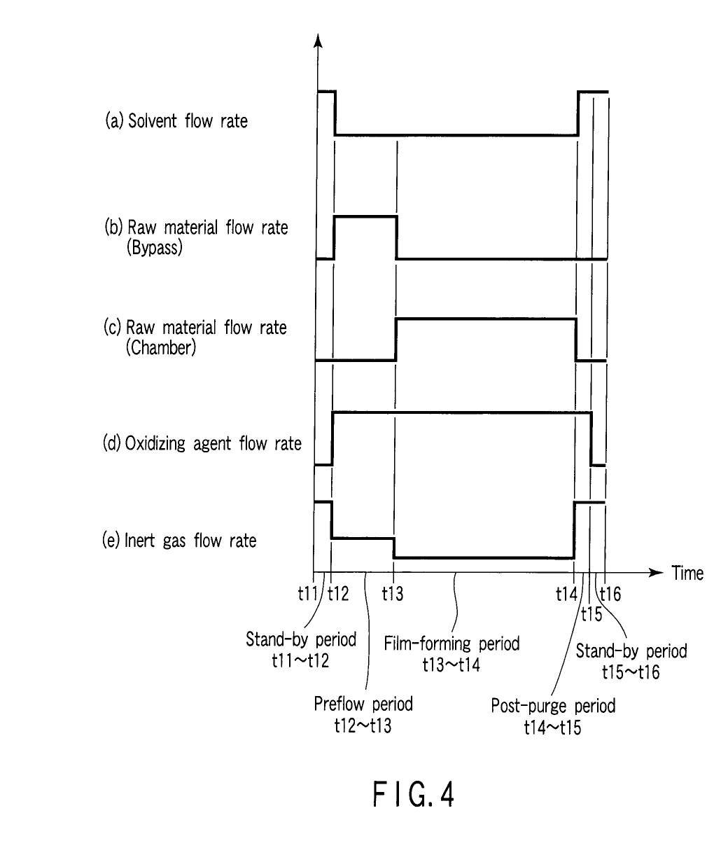

Next, Comparative Example wherein the aforementioned apparatus is operated in the same manner as the conventional method will be explained with reference to FIG. 4 for the purpose of comparing it with the aforementioned operation of above Example. By the way, the explanations on some portions of Comparative Example which are identical with those of aforementioned Example will be omitted.

In this Comparative Example, the flow rate of oxidizing agent (FIG. 4(d)) and the flow rate of inert gas (FIG. 4(e)) differ from those of the aforementioned Example. Namely, the introduction of oxidizing gas into the chamber 132 is initiated at the timing t12 when the stand-by time period t11-t12 is shifted to the preflow time period t12-t13 (FIG. 4(d)). Further, once the raw material flow rate (bypass) is stabilized (FIG. 4(b)), the raw material gas of the raw material flow rate (chamber) is fed to the chamber 132 to perform the deposition of film (FIG. 4(c)).

As described above, in the case of the conventional method, since the introduction of oxidizing gas into the chamber 132 is initiated at the preflow time period t12-t13 prior to the formation of film, the surface of substrate W is caused to oxidize due to the oxidizing agent. When the formation of film is initiated under the condition wherein the surface of substrate W is oxidized, the interface between the underlying layer and the deposited film layer is badly affected (surface oxidation), thus deteriorating the film quality of the deposited film layer.

[Method of Manufacturing Capacity Element and Semiconductor Device]

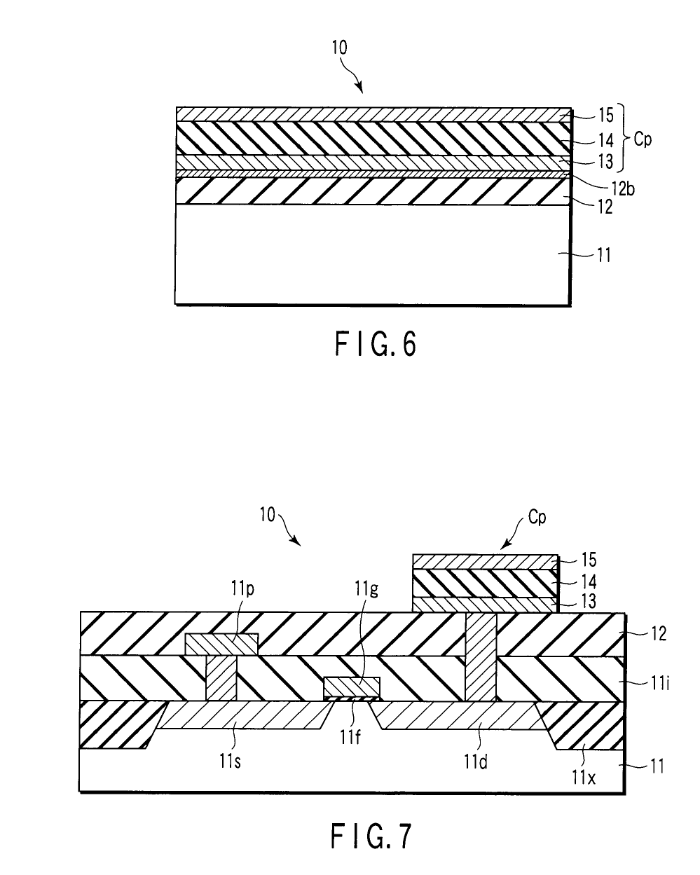

FIG. 6 is a cross-sectional view schematically illustrating the capacity element formed by means of the manufacturing method according to this example. An SiO₂ insulating film 12 is formed on a silicon substrate 11. On this insulating film 12 is formed a lower electrode 13 made of a layer of metal such as Ir, Ru, etc. with a barrier layer 12b being interposed therebetween. This lower electrode 13 can be formed by means of sputtering method using a metal target such, for example, as Ir, Ru, etc. Subsequently, by making use of the aforementioned apparatus, a dielectric layer 14 made of PZT or BST is formed on this lower electrode 13 by means of MOCVD method. This dielectric layer 14 is formed of a metal oxide having a perovskite-type crystal structure which can be formed through a reaction between an organometallic material gas and an oxidizing gas according to the method of aforementioned Example. An upper electrode 15 made of Pt, Ir, IrO₂ is formed on the dielectric layer 14 by means of sputtering method.

A capacity element Cp is constituted by the laminate structure consisting of the lower electrode 13, the dielectric layer 14 and the upper electrode 15. This capacity element Cp is formed as part of the semiconductor device 10 comprising a substrate 11 and a circuit structure formed on the substrate 11. By the way, it is preferable that an adhesion layer formed of Ta or Ti, or a barrier layer 12b made of TaN or TiN is interposed between the insulating layer 12 formed of SiO₂ and the lower electrode 13 formed of a metal layer such as Ir, Ru, etc.

FIG. 7 is a cross-sectional view schematically illustrating a semiconductor device provided with FeRAM which is formed on the substrate 11. In the same manner as in the case of forming an ordinary MOS transistor, memory cell transistors (11s, 11f, 11d and 11x) of FeRAM are formed on the substrate 11. Namely, the surface of substrate 11 is partially removed to form an element isolation film 11x, thus forming an element isolation structure. Next, an impurity is implanted into part of the element region that has been isolated by the element isolation structure to thereby form a source region 11s and a drain region 11d. A gate electrode (word line) 11g is formed, via a gate insulating film 11f, at a surface of the region between the source region 11s and the drain region 11d. Subsequently, a first interlayer insulating film 11i is formed on the gate electrode 11g and then a wiring (bit line) 11p is electrically connected with the source region 11s through a contact hole formed in the first interlayer insulating film 11i.

Meanwhile, a second interlayer insulating film 12 is further formed on the wiring 11p and then a lower electrode 13 is formed in the same manner as shown in FIG. 6. This lower electrode 13 is electrically connected with the drain region 11d through a contact hole formed in the second interlayer insulating film 12 and in the first interlayer insulating film 11i. In the same manner as described above, a dielectric layer 14 and an upper electrode 15 are laminated on the lower electrode 13, thereby obtaining a capacity element Cp of the same kind as described above. Additionally, a semiconductor device 10 provided with the capacity element Cp as a memory cell (FeRAM) of ferroelectric substance can be obtained.

[Function and Effects]

As describe in Comparative Example, when an oxidizing gas is introduced in advance into the chamber 132 under the condition wherein the inflow of an organometallic material gas is not yet started, the oxidizing gas is permitted to contact with the substrate W under high temperatures. As a result, when the underlying surface of the substrate W is constituted by the surface of metal layer such as Ir and Ru, the surface is partially oxidized. Although the magnitude of oxidation in this case may be determined depending on the oxidizing power of the oxidizing gas, on the partial pressure of the oxidizing gas, on the temperature of substrate, on the material of the metal layer, etc., the surface may be turned into an incomplete and non-reproducible oxidized state.

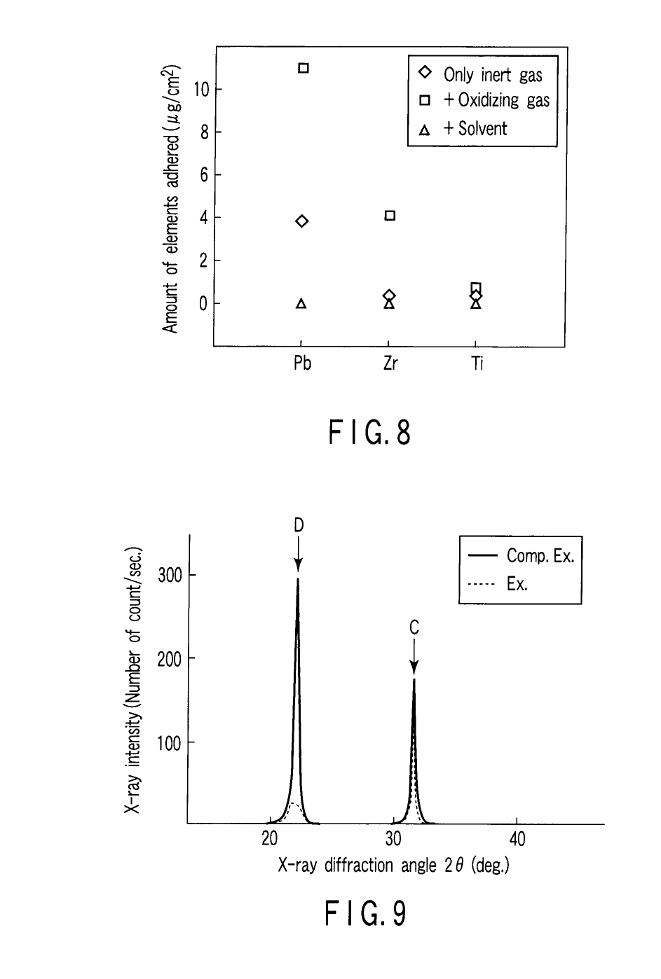

Further, even under the condition wherein the inflow of an organometallic material gas is not started, deposit may be generated on the surface of substrate W due to the introduction of an oxidizing gas. FIG. 8 is a graph illustrating the results of experiment which was performed by making use of an apparatus which was actually employed in the formation of film of PZT in the past. In this experiment, a metal layer such as Ir and Ru was formed on a silicon substrate to obtain a substrate W, which was then placed in the chamber 132. Then, the interior of the chamber 132 was evacuated while introducing a predetermined gas so as to make the pressure thereof into 533.3 Pa, after which the substrate W was heated up to a preset temperature of 625° C. and maintained at this temperature for 300 seconds. Subsequently, the substrate W thus treated was analyzed by making use of a fluorescent X-ray analyzer to determine the amounts of each of Pb, Zr and Ti that have been adhered onto the surface of substrate W. Herein, the rhomboid mark in FIG. 8 represents the result obtained when only the inert gas was introduced into the chamber 132, the square mark represents the result obtained when the oxidizing gas (O₂) was introduced together with the inert gas into the chamber 132 so as to make the partial pressure of the oxidizing gas equivalent to that of the stand-by time period of Comparative Example, and the triangular mark represents the result obtained when the solvent was introduced together with the inert gas into the chamber 132 so as to make the flow rate of the solvent equivalent to that of the aforementioned stand-by time period.

According to the above experiment, when oxygen was introduced together with the inert gas into the chamber 132, Pb, Zr and Ti were apparently deposited on the surface of metal layer of substrate W. This seems to indicate that the raw material left remained in the chamber 132 during the process of forming a film of PZT which was performed before the experiment or Pb dissociated from the inner wall of chamber 132 were permitted to react with oxygen to thereby allow these elements to deposit on the substrate W. Further, even in the case where only the inert gas was introduced into the chamber 132, Pb was permitted, though the quantity thereof was very small, to adhere to the surface of substrate W.

On the other hand, when the solvent was introduced into the chamber 132, the adhesion of all of Pb, Zr and Ti to the substrate W was scarcely admitted, thus indicating that the surface of metal layer was kept in a clean state. Accordingly, it was assumed that when an oxidizing gas was introduced into the chamber 132 prior to the formation of film, the raw material left remained in the chamber 132 was permitted to react with the oxidizing gas to allow such a deposit that could not be controlled to adhere to the surface of substrate and, for this reason, it was impossible to control the interface between the metal layer and the dielectric layer, resulting in the deterioration of reproducibility of the surface condition of the metal layer and hence badly affecting the reproducibility of the film quality of dielectric layer.

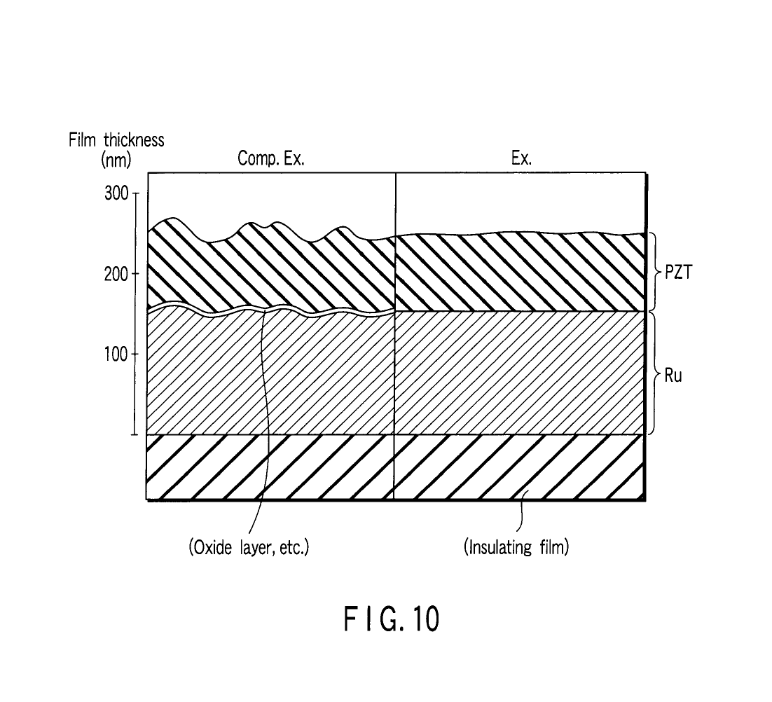

Next, by making use of the substrate W comprising a metal layer made of Ru and formed on a silicon substrate with an insulating film being interposed therebetween, a PZT thin film was formed on the metal layer by making use of the above-described apparatus and the surface of the substrate was subjected to X-ray analysis. FIG. 9 shows part of the spectrum of the X-ray analysis (XRD). The solid line in FIG. 9 represents the result of the PZT thin film that was formed according to the method of Comparative Example, and the broken line represents the result of the PZT thin film that was formed according to the method of above-described Example. In this graph, “C” indicates the diffraction peaks derived from the (110) face and (101) face of PZT, and “D” indicates the diffraction peaks derived from the (100) face of PZT. It will be recognized from FIG. 9 that while the diffraction peaks “C” derived from the (110) face and (101) face of PZT were almost the same with each other, the diffraction peaks “D” derived from the (100) face of PZT were found quite different from each other, i.e. the diffraction peak “D” of Example was greatly lowered. From these results, it was assumed that, in the Example, the orientation was made more excellent and hence the crystal structure was made more uniform. With respect to the prominent decrease of the diffraction peak derived from the (100) face of PZT in Example, it would not raise any problem since the crystal exhibiting (100) face of PZT inherently does not show ferroelectricity. This is originated from the fact that the direction of polarization of PZT is <001>.

FIG. 10 is a cross-sectional view schematically illustrating the surface roughness of the PZT dielectric layers of Comparative Example and of Example shown in FIG. 9. A left half region of FIG. 10 illustrates Comparative Example and a right half region thereof illustrates Example. In both of Comparative Example and of Example, the thickness of Ru metal layer (lower electrode) was set to about 130 nm and thickness of PZT dielectric layer was set to about 100 nm. It will be recognized from FIG. 10 that the surface roughness of the PZT dielectric layer of Example was prominently improved as compared with that of the PZT dielectric layer of Comparative Example. Especially, since the morphology of the surface of PZT dielectric layer of Example was improved, it is expected that the state of interface between the upper electrode and the dielectric layer can be stabilized, thereby making it possible to improve the electric properties (for example, reduction of leak current) of capacity element and, at the same time, to facilitate the execution of subsequent processes such as lithography and etching.

Furthermore, since the morphology of the surface of dielectric layer can be improved, it is expected to obtain the effect that in-film particle measurement can be easily performed. According to the prior art, when a ferroelectric layer such as PZT is formed by means of MOCVD method, the facet that will be developed on the surface of crystal as the crystal growth of PZT is increased is also caused to grow, so that it has been very difficult to flatten the surface morphology of PZT layer. In the ordinary particle measurement, laser beam is irradiated onto the surface of substrate to obtain scattered laser beam from the particle and then the scattered laser beam thus obtained is detected to count the number of particles. However, there is a problem that since the surface morphology of PZT ferroelectric layer is poor, it has been very difficult to determine whether the scattered laser beam is originated from the particles or originated from the facet on the surface of the PZT crystal, thus making it difficult to satisfactorily perform the in-film particle measurement of PZT ferroelectric layer. However, if it is possible to improve the surface morphology as seen in this Example, it is possible to extremely suppress the scattered laser beam that will be originated from the facet on the surface of the PZT crystal, thus making it possible to easily and accurately perform the in-film particle measurement of PZT ferroelectric layer.

By the way, although the explanation of this Example is directed to the case where a dielectric layer (ferroelectric layer) formed of a metal oxide (polycrystal) having a perovskite-type crystal structure is formed as described above, the dielectric layer to be formed on a metal layer may not be one having a perovskite-type crystal structure exhibiting ferroelectricity. Namely, the present invention is not intended to exclude the cases wherein a polycrystalline thin film exhibiting other orientated states or an amorphous thin film is formed on the metal layer. Even with these thin films, it would be effective for use as a dielectric substance or as an insulating substance. The amorphous thin film can be polycrystallized by means of heating after the formation thereof.

As described above, according to this Example, since the preceding period t3-t4 for feeding a raw material gas under the condition where the supply of oxidizing gas is stopped is provided immediately before the film-forming time period t4-t5 wherein a dielectric layer is formed through a reaction between a raw material gas and an oxidizing gas, a substrate to be treated can be placed in a reducing atmosphere in this preceding period t3-t4, thereby preventing the underlying surface for forming the film from being insufficiently oxidized.

Further, since an oxidizing gas is not introduced in this preceding period t3-t4, it is possible to prevent a deposit which cannot be controlled in composition from adhering onto the underlying surface, thereby making it possible to perform the deposition of film under the condition wherein the underlying surface is maintained in a relatively clean state. As a result, it is possible to avoid the deterioration of reproducibility and the instability of the electric properties of capacity element that may be caused due to the undesirable condition of interface between the underlying surface and the dielectric layer and, at the same time, it is possible to improve the film quality of the dielectric layer to be formed on the underlying surface. Further, it is also expected to improve the flatness of the surface of dielectric layer (improvement of morphology). Therefore, it is possible to minimize the non-uniformity of electric properties of capacity element and to stabilize the electric properties of capacity element.

The organometallic material gas to be used in the preceding period t3-t4 may not required to be completely the same as the raw material gas. For example, if a raw material gas consisting of a mixture of three kinds of organometallic material gas is to be fed in the film-forming time period t4-t5, at least one kind of organometallic material gas among these three kinds of organometallic material gas may be employed in the preceding period t3-t4. In this Example however, in order to realize a continuous shifting of process from the preceding period t3-t4 to the film-forming time period t4-t5, the same kind of raw material gas as that employed in the film-forming time period t4-t5 was employed in the preceding period t3-t4, thus making it possible to minimize any change in feeding condition of raw material gas in the initial stage of the film-forming time period t4-t5. As a result, it is now possible to stabilize the composition of dielectric layer and to easily control the supply of the organometallic material gas. In this case, if the composition of raw material gas in the preceding period t3-t4 is substantially the same as the composition of raw material gas in the film-forming time period t4-t5, it is possible to substantially disappear any change in composition of raw material gas in the initial stage of the film-forming time period t4-t5. Further, if the partial pressure of raw material gas in the preceding period t3-t4 is made substantially the same as the partial pressure of raw material gas in the film-forming time period t4-t5, it is possible to substantially disappear any change in partial pressure of raw material gas in the initial stage of the film-forming time period t4-t5, thus making it possible to stably initiate the deposition of film.

In this Example, the preceding period t3-t4 is provided immediately before the film-forming time period t4-t5. In this preceding period t3-t4, the raw material gas is introduced into the chamber 132 under the condition wherein the introduction of an oxidizing gas is suspended, and then the raw material gas and the oxidizing gas are introduced into the chamber 132 in the film-forming time period t4-t5, thus preventing the surface condition of underlying layer from turned into an uncontrollable state. However, it is also possible, in the preceding period t3-t4, to introduce a vaporized gas of organic solvent into the chamber without introducing the organometallic material gas under the condition wherein the introduction of an oxidizing gas is suspended. In this case, raw material elements would not be adhered to the surface of substrate, but the process of film deposition can be initiated with the surface of substrate being kept in a clean state in the absence of the oxidation thereof, thus making it possible to secure the controllability of underlying surface. As a result, it is now possible to improve the homogeneity of the thin film to be obtained and to improve the surface morphology of the thin film.

Further, it is also possible, in the preceding period t3-t4, to provide a first time period in which a vaporized gas of organic solvent is introduced into the chamber without introducing the organometallic material gas under the condition wherein the introduction of an oxidizing gas is suspended, and also to provide, after the first time period, a second time period wherein the raw material gas is introduced into the chamber under the condition wherein the introduction of an oxidizing gas is suspended, the aforementioned film-forming time period being initiated subsequent to this second time period. In this case also, the cleanliness of the surface of substrate can be maintained in the first time period and the raw material molecules are enabled to uniformly adhere onto the surface of substrate in the second time period, thus obtaining almost the same effects as obtained in the above-described Example.

The aforementioned may be modified in such a manner that, in the first time period of the preceding period t3-t4, part of plural kinds of organometallic material gas is introduced into the chamber under the condition wherein the introduction of an oxidizing gas is suspended, and then, in the second time period, all kinds of organometallic material gas are introduced into the chamber under the condition wherein the introduction of an oxidizing gas is suspended, immediately after which the oxidizing gas is newly introduced into the chamber under the condition wherein the introduction of the same kinds of raw material gas as employed in the second time period are maintained, thus initiating the deposition of film.

By the way, if it is desired to selectively introduce the vaporized gas of organic solvent and the raw material gas (organometallic gas or a mixed gas consisting of the organometallic gas and the vaporized gas of organic solvent) into the film-forming chamber, it is preferable to provide a gas supply system for introducing only the vaporized gas of organic solvent in separate from the aforementioned raw material gas supply system which is designed to introduce the raw material gas as explained in the above-described Example, these gas supply systems being disposed side by side. By doing so, it is possible, through the manipulation of valves of gas supply systems, to easily and accurately perform the change-over of the preceding period t3-t4 and the film-forming time period t4-t5 as well as the first time period, the second time period and the film-forming time period t4-t5.

Although this Example has been explained with reference to the case wherein ferroelectric PZT is formed into a film as a dielectric layer, the present invention is not limited to such a case. It is possible, for example, to apply the present invention to ferroelectric substances wherein elements such as La, Ca, Nb are added to PZT, and to composite ferroelectric substances including PbTiO₃, SrBi₂Ta₂O₉, BiLaTiO, etc.

According to the present invention, since the supply of an oxidizing gas to a metal layer without the accompaniment of the supply of at least part of organometallic material gas is prevented at a stage before the film-forming stage, it is possible to prevent the generation of incomplete oxidation of the surface of metal layer as well as the adhesion, due to the oxidizing gas, of deposit on the surface of metal layer. As a result, it is possible to inhibit the generation of non-uniformity of the surface of metal layer. Moreover, since a metal oxide film is no longer existed between the metal layer and the dielectric layer, it is possible to secure the stability and reproducibility of the state of interface and to improve the film quality of dielectric layer as well as the reproducibility thereof. As a result, it is possible to realize excellent effects such as the improvement of the electric properties of capacity element and the improvement in flatness of the surface of dielectric layer.

By the way, the method for manufacturing a capacity element, the method of manufacturing a semiconductor device, and the semiconductor-manufacturing apparatus according to the present invention are not limited those described in the drawings but they can be, of course, variously modified within the spirits of the present invention.

What is claimed is:

1. A method of manufacturing a capacity element, which comprises the steps of:
(a) forming an insulating film on a substrate to be processed;
(b) forming a lower electrode layer on the insulating film;
(c) feeding a vaporized organic solvent onto the lower electrode layer under a condition wherein an oxidizing gas is prevented from feeding in a first step (c1), and feeding one or plural kinds of the organometallic material gas together with the oxidizing gas to the lower electrode layer in a second step (c2), said first step (c1) and said second step (c2) being continuously performed in a chamber, thereby forming a dielectric layer on the lower electrode; and
(d) forming an upper electrode layer on the dielectric layer.

2. The method according to claim 1, wherein the lower electrode layer to be formed in the step (b) comprises a platinum group element.

3. The method according to claim 2, wherein the platinum group element is Ir.

4. The method according to claim 2, wherein the platinum group element is Ru.

5. The method according to claim 1, wherein the dielectric substance to be formed in the step (c) is a ferroelectric substance.

6. The method according to claim 5, wherein the dielectric substance to be formed in the step (c) is formed of Pb(Zr, Ti)O₃.

7. The method according to claim 1, wherein the organometallic material gas is one which can be created through the vaporization of a solution of organometallic material in a vaporizer.

8. The method according to claim 7, wherein the solution of organometallic material is one which can be created through the dissolution of the organometallic material in an organic solvent.

9. The method according to claim 8, wherein the organic solvent is butyl acetate.

10. A method of manufacturing a capacity element, which comprises the steps of:
(a) forming an insulating film on a substrate to be processed;
(b) forming a lower electrode layer on the insulating film;
(c) feeding one or plural kinds of organometallic material gas to the lower electrode layer under a condition wherein an oxidizing gas is prevented from feeding in a first step (c1), and feeding the organometallic material gas having the same composition as that employed in the a first step (c1) together with the oxidizing gas onto the lower electrode layer in a second step (c2), said first step (c1) and said second step (c2) being continuously performed in a chamber, thereby forming a dielectric layer on the lower electrode; and
(d) forming an upper electrode layer on the dielectric layer.

11. The method according to claim 10, wherein said one or plural kinds of organometallic material gas are fed together with vaporized organic solvent in the first step (c1).

12. The method according to claim 10, wherein the lower electrode layer to be formed in the step (b) comprises a platinum group element.

13. The method according to claim 12, wherein the platinum group element is Ir.

14. The method according to claim 12, wherein the platinum group element is Ru.

15. The method according to claim 10, wherein the dielectric substance to be formed in the step (c) is a ferroelectric substance.

16. The method according to claim 15, wherein the dielectric substance to be formed in the step (c) is formed of Pb(Zr, Ti)O₃.

17. The method according to claim 10, wherein the organometallic material gas is one which can be created through the vaporization of a solution of organometallic material in a vaporizer.

18. The method according to claim 17, wherein the solution of organometallic material is one which can be created through the dissolution of the organometallic material in an organic solvent.

19. A semiconductor manufacturing apparatus comprising:
a chamber which is equipped with a mounting table for supporting a substrate and configured to surround the substrate;
a raw material feeding section for feeding one or plural kinds of organometallic material gas, an oxidizing gas and a vaporized organic solvent, respectively, to the chamber;
an exhaust section for exhausting the interior of the chamber; and
a control section for controlling the raw material feeding section in such a manner that said one or plural kinds of organometallic material gas and/or the vaporized organic solvent are fed into the chamber from the raw material feeding section without feeding the oxidizing gas into the chamber in a first time period, and then the organometallic material gas is fed together with the oxidizing gas into the chamber from the raw material feeding section in a second time period, and that a feeding action in the first time period and a feeding action in the second time period are successively executed.

20. The semiconductor manufacturing apparatus according to claim 19, which further comprises a vaporizer for vaporizing the solution of the organometallic material, thus generating an organometallic material gas.
